(19) United States
(12) Patent Application Publication
(10) Pub. No.: US 2013/0010427 A1
(43) Pub. Date: Jan. 10, 2013

(54) ELECTRONIC DEVICE WITH HEAT DISSIPATION UNIT

(75) Inventors: JU-SHAN LIN, Tu-Cheng (TW); TE-JEN SUNG, Tu-Cheng (TW); GUANG-LIANG LUO, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/217,167

(22) Filed: Aug. 24, 2011

(30) Foreign Application Priority Data
Jul. 5, 2011 (CN) 201110186616.9

(51) Int. Cl. H05K 7/20

(52) U.S. Cl. 361/697; 361/695

(57) ABSTRACT

A heat dissipation unit for radiating heat produced by at least one heat source of an electronic device includes a fan, at least an electrical connector, and a latching member. The fan has at least one power cord. The at least one connector is connected to the at least one power cord and is engageable with a power connector of a power supply unit of the electronic device. The latching member corresponds to the power connector for clasping the electrical connector therein. The electrical connector is clasped in the latching member for being aligned with the power connector of the electronic device.

### BACKGROUND

1. Technical Field

The present disclosure relates to electronic devices, and in particular, to an electronic device with a heat dissipation unit.

2. Description of Related Art

A heat dissipation unit is often disposed in an electronic device such as a notebook computer for radiating heat. The heat dissipation unit often includes a heat sink and a fan with a power cord adjacent to the heat sink. In assembly, the power cord is connected to an electrical connector which is plugged into a power connector of a power supply unit such that the power supply unit can supply power to the fan. When plugging the electrical connector into the power connector, the electrical connector should be aligned with the power connector. This may be difficult and inconvenient if the electrical connector and the power connector are both small, and further reduce the assembly efficiency of the electronic device.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of part of an electronic device according to an embodiment of the present disclosure. The electronic device includes a heat dissipation unit.

FIG. 2 is a schematic view of the heat dissipation unit of FIG. 1.

FIG. 3 is an enlarged view of the III part of FIG. 2.

FIG. 4 is a partially exploded view of the heat dissipation unit of FIG. 1.

FIG. 5 is similar to FIG. 4 but from a reverse angle.

### DETAILED DESCRIPTION

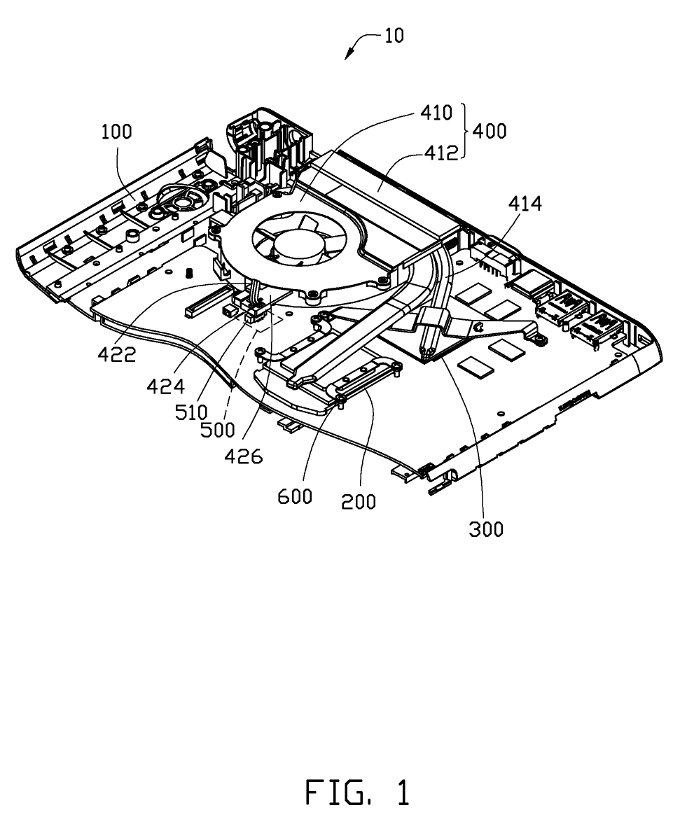

Referring to FIG. 1, an electronic device 10 includes a housing 100, a heat dissipation unit 400, and a power supply unit 500 with a power connector 510. The heat dissipation unit 400 is thermally connected to heat sources of the electronic device 10, for example, a central processing unit (CPU) 200 and a display card 300 of the electronic device 10, for absorbing and removing heat produced by the heat sources. The heat dissipation unit 400 is also connected to the power supply unit 500 by the power connector 510. In some embodiments, the electronic device 10 is a notebook computer. In other embodiments, the electronic device 10 may be other devices with a heat dissipation unit, and the heat sources may be other components of the electronic device 10.

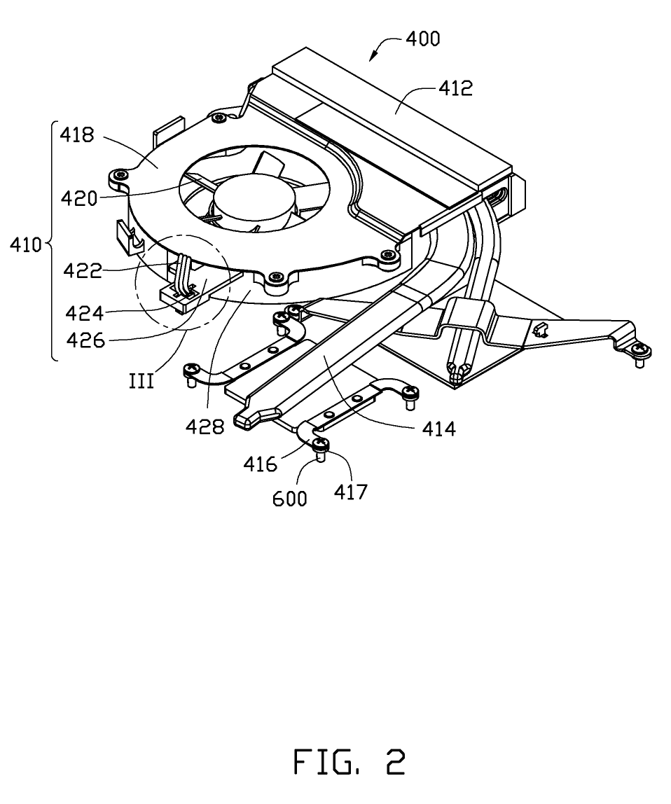

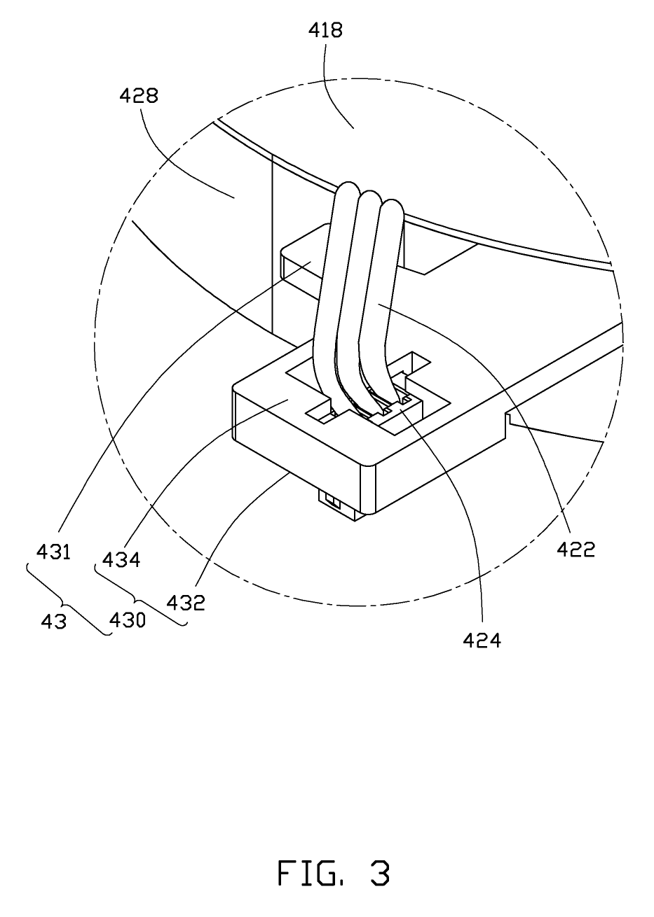

Referring also to FIGS. 2 and 3, the heat dissipation unit 400 includes a fan 410, a heat sink 412, and a number of fixing members 416. The heat sink 412 includes two heat pipes 414 and a number of fins (not shown). The heat pipes 414 are respectively connected to the CPU 200 and to the display card 300 for absorbing heat produced by the CPU 200 and the display card 300 and transferring the heat to the fins for further dissipation. In the illustrated embodiment, the heat sink 412 is integrally formed and is connected to the housing 100 by a number of screws 600. The fixing members 416 are disposed on the heat sink 412 for respectively passing the screws 600 through. Each of the fixing members 416 includes a ring 417 tightly sleeved on the corresponding screw 600. Each screw 600 is attached to the heat sink 412 by the corresponding ring 417 and thus is captive in the heat sink 412 even before the heat sink 412 is mounted to the housing 100. In the illustrated embodiment, each ring 417 is made of elastic material. The fan 410 is used for forcing airflow towards the sink fins to speed up the dissipation of the heat.

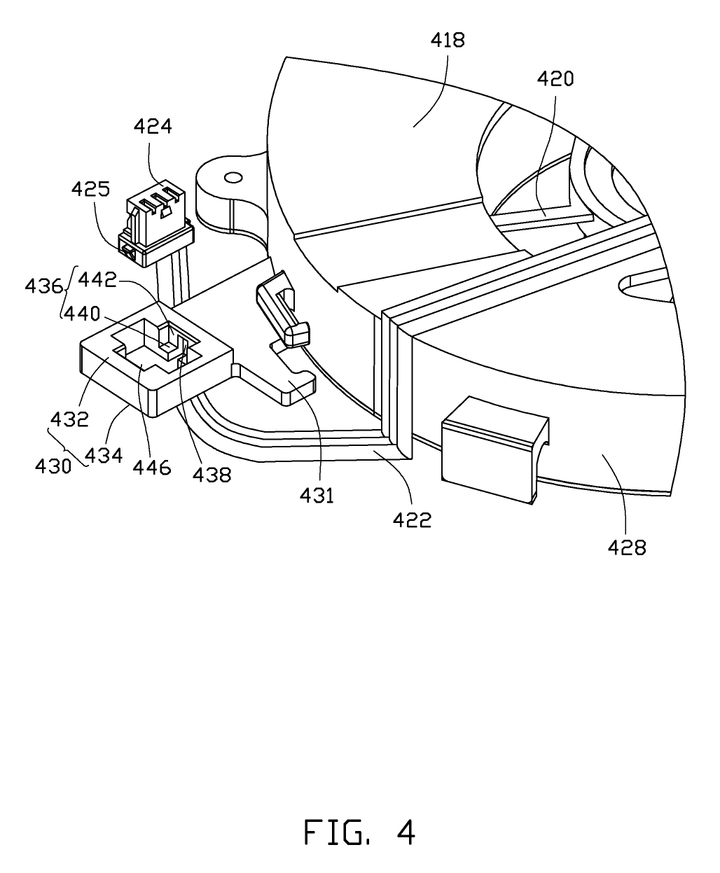

The fan 410 includes a case 418, an impeller 420 received in the case 418, three power cords 422, an electrical connector 424 with the power cords 422 connected thereto, and a latching member 426. The electrical connector 424 is clasped in the latching member 426 and corresponds to the power connector 510. In the illustrated embodiment, the electrical connector 424 includes two elastic portions 425 (see FIG. 4) for engaging with the latching member 426. The case 418 includes an approximately circular first side wall 428, and the latching member 426 protrudes from the first side wall 428.

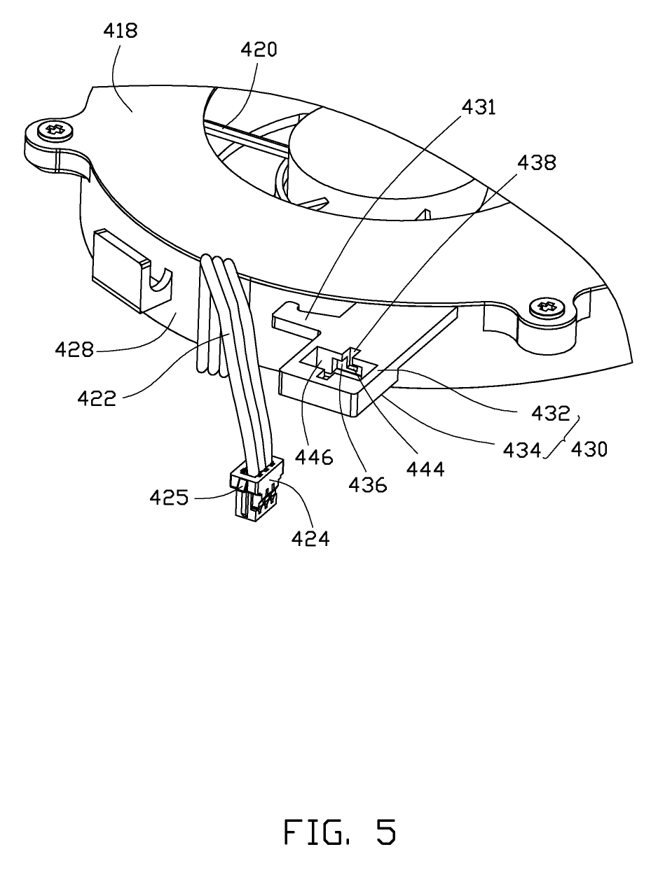

Referring to FIG. 4, the latching member 426 includes a main body 430 protruding from the first side wall 428 and a hook 431 protruding from the main body 430. The main body 430 includes a first side 432 adjacent to the power connector 510, and a second side 434 opposite to the first side 432. In the first side 432 is a cavity to form a receiving portion 436 corresponding to the power connector 510 for receiving the electrical connector 424. The receiving portion 436 includes a bottom plate 440 and two opposite side walls 442 perpendicularly protruding from the bottom plate 440 connected to the first side 432. Each side wall 442 recesses to define a slot 438 for receiving two elastic portions 425. Each slot 438 is spaced from the first side 432 and is open at the second side 434. As shown in FIG. 5, each slot 438 includes an abutting wall 444 parallel to the first side 432 for abutting the elastic portions 425.

A through hole 446 is defined in the main body 430 for passing the electrical connector 424 and the power cords 422 through. In the illustrated embodiment, the through hole 446 is a hole in the shape of a cross, running through a part of the bottom plate 440 of the receiving portion 436 and partly surrounded by the two slots 438. The hook 431 is spaced from the first side wall 418 of the fan 410 to define an accommodation space for the power cords 422.

When the fan 410 is to be mounted to the housing 100, the electrical connector 424 with the power cords 422 connected thereto passes through the main body 430 through the through hole 446 to correspond to the first side 432. In this state, the electrical connector 424 is not aligned with the receiving portion 436, and the elastic portions 425 are not received in the slots 438. Then the electrical connector 424 is rotated approximately 90 degrees to be aligned with the receiving portion 436. When the electrical connector 424 is received in the receiving portion 436, each elastic portion 425 is received in the corresponding slot 438 and abuts the corresponding abutting wall 444. Therefore, the electrical connector 424 is clasped in the latching member 426 and held firmly in place. After the electrical connector 424 is clasped in the latching member 426, the fan 410 is mounted to the housing 10. Now, the receiving portion 436 and the electrical connector 424 received therein do correspond to the power connector 510. Thus, the electrical connector 424 can be easily plugged into the power connector 424. Also, since the hook 431 and the case 418 of the fan 410 define the accommodation space for the power cords 422, the overall volume taken up by the heat dissipation unit 400 can be reduced.

With the latching member 426 for clasping the electrical connector 424, the electrical connector 424 can be aligned with the power connector 510 after the heat dissipation unit 400 is mounted to the housing 100. The electrical connector 424 can thus connect easily to the power connector 510. Additionally, the heat sink 412 may be integrally formed and the screws 600 are always in place on the heat sink 412 by virtue of the fixing members 416, therefore, the screws 600 self-align with the screw holes defined in the housing 100 as the heat sink 412 is correctly placed in the housing 100.

Even though some information and the advantages of the present embodiments have been set forth in the foregoing description, together with details of the structures and functions of the present embodiments, the disclosure is illustrative only; and changes may be made in detail, especially in matters of the shape, size, and arrangement of parts within the principles of the present embodiments to the full extent indicated by the broad general meaning of the terms in which the appended claims are expressed.

What is claimed is:

1. A heat dissipation unit for radiating heat produced by at least one heat source of an electronic device, comprising:
a fan with at least one power cord;
at least an electrical connector connected to the at least one power cord and being engageable with a power connector of a power supply unit of the electronic device; and
a latching member corresponding to the power connector for clasping the electrical connector therein;
wherein when the electrical connector is clasped in the latching member, the electrical connector is aligned with the power connector of the electronic device.

2. The heat dissipation unit as claimed in claim 1, wherein the heat dissipation unit further comprises a heat sink, the heat sink is connected to the at least one heat source for absorbing heat produced by the component, the fan generates airflow towards the heat sink for dissipating the heat.

3. The heat dissipation unit as claimed in claim 2, wherein the heat sink is integrally formed and is connected to a housing of the electronic device by screws.

4. The heat dissipation unit as claimed in claim 3, wherein the heat sink comprises a plurality of fixing members engaging with the screws for respectively passing the screws through, and each fixing member comprises a ring sleeved on the corresponding screw for attaching the corresponding screw to the heat sink.

5. The heat dissipation unit as claimed in claim 4, wherein each ring is made of elastic member.

6. The heat dissipation unit as claimed in claim 2, wherein the latching member comprises a main body protruding from the fan, one side of the main body corresponding to the power connector recesses to form a receiving portion corresponding to the power connector for receiving the electrical connector therein.

7. The heat dissipation unit as claimed in claim 6, wherein a through hole is defined in the main body for passing the electrical connector and the at least one power cord through.

8. The heat dissipation unit as claimed in claim 7, wherein the electrical connector comprises two elastic portions, the receiving portion comprises two opposite first side walls, and each first side wall defines a slot for engaging with the corresponding elastic portion to restrict the electrical connector from moving away from the receiving portion.

9. The heat dissipation unit as claimed in claim 8, wherein each slot comprises an abutting wall spaced from the side of the main body which is recessed to form the receiving portion, each elastic portions abuts the corresponding abutting wall.

10. The heat dissipation unit as claimed in claim 8, wherein the receiving portion comprises a bottom plate connecting the first side walls, the through hole runs through a part of the bottom plate.

11. The heat dissipation unit as claimed in claim 6, wherein the fan comprises a case and an impellor received in the case, and the latching member protrudes from the case.

12. The heat dissipation unit as claimed in claim 11, wherein the latching member further comprises a hook protruding from the main body, the case includes an arch second side wall, the hook and the second side wall defines an accommodation space for the at least one power cord.

13. An electronic device, comprising:
a power supply unit with a power connector;
at least one heat source; and
a heat dissipation unit connected to the at least one heat source for radiating heat produced by the at least one heat source, comprising:
a fan with at least one power cord;
an electrical connector connected to the at least one power cord and being engageable with the power connector; and
a latching member corresponding to the power connector for clasping the electrical connector therein;
wherein when the electrical connector is clasped in the latching member, the electrical connector is aligned with the power connector.

14. The electronic device as claimed in claim 13, wherein the heat dissipation unit further comprises a heat sink, the heat sink is connected to the at least one heat source for absorbing heat produced by the component, the fan generates airflow towards the heat sink for dissipating the heat, the at least one power cord is also connected to the fan.

15. The electronic device as claimed in claim 14, wherein the electronic device further comprises a housing for mounting the heat dissipation unit therein, the heat sink is integrally formed and is connected to the housing by screws.

16. The electronic device as claimed in claim 15, wherein the heat sink comprises a plurality of fixing members engaging with the screws respectively for attaching the screws to the heat sink before the heat sink is mounted to the housing.

17. The electronic device as claimed in claim 15, wherein the latching member comprises a main body protruding from the fan, one side of the main body corresponding to the power connector recesses to form a receiving portion corresponding to the power connector for receiving the electrical connector therein.

18. The electronic device as claimed in claim 17, wherein the electrical connector comprises two elastic portions, the receiving portion comprises two opposite first side walls, and each first side wall defines a slot for engaging with the corresponding elastic portion to restrict the electrical connector from moving away from the receiving portion.

19. The electronic device as claimed in claim 18, wherein a through hole is defined in the main body for passing the electrical connector and the at least one power cord through.

20. The electronic device as claimed in claim 13, wherein the at least one heat source comprises a central processing unit and a display card of the electronic device.
